(19) United States
(12) Patent Application Publication
(10) Pub. No.: US 2019/0360075 A1
(43) Pub. Date: Nov. 28, 2019

(54) Lead-Free Solder Alloy Comprising Sn, Bi and at Least One of Mn, Sb, Cu and its Use for Soldering an Electronic Component to a Substrate

(71) Applicant: Interflux Electronics N.V., Gent (BE)

(72) Inventors: Daniel Werkhoven, Gent (BE); Annick Peeters, Gent (BE); Ralph Lauwaert, Gent (BE); Isabelle Maris, Gent (BE); Bart Van De Lisdonk, Gent (BE); Steven Teliszewski, Gent (BE)

(21) Appl. No.: 16/331,329

(22) PCT Filed: Sep. 12, 2017
(86) PCT No.: PCT/EP2017/072904

§ 371 Date: Mar. 7, 2019

(30) Foreign Application Priority Data
Sep. 12, 2016 (EP) 16188368.1

(51) Int. Cl. C22C 12/00; C22C 13/02; H05K 3/34; B23K 35/26

(52) U.S. Cl. CPC C22C 12/00; B23K 35/262; H05K 3/3457; C22C 13/02

(57) ABSTRACT

A solder alloy comprises 38.0-42.0 wt % bismuth (Bi), 0.01-2 wt % of at least one further element chosen from the group of manganese (Mn), antimony (Sb) and copper (Cu), the balance being tin (Sn), and is at least substantially free of nickel (Ni), and further preferably substantially free of silver (Ag). The solder alloy may be combined with a halide-free solder flux to constitute a solder paste, solder bath or solder wire. The solder paste is for instance used for soldering electronic component packages such as quad flat non-leaded (QFN) packages or for soldering surface mount devices (SMD), resulting in low void formation. The solder alloy may also be applied by means of wave-soldering or selective soldering.

### FIELD OF THE INVENTION

The invention relates to a lead free tin-bismuth solder composition.

The invention further relates to the use of such a lead-free tin-bismuth solder composition for soldering an electronic component package to a substrate, which electronic component package is provided with a plurality of contacts and an exposed die pad, which contacts and which die pads are soldered to associated contacts on the substrate.

### BACKGROUND OF THE INVENTION

Traditionally, solder compositions were based on eutectic lead-tin alloy, which has a melting point around 180° C. This composition was known to have good bonding properties. However, the use of this solder composition is no longer allowed due to the toxicity of lead. In the past twenty years, a tin-based solder has become the standard material for soldering in microelectronics. More particularly, this tin-based solder is an alloy of tin (Sn), silver (Ag) and copper (Cu), also known as SAC solder. Typically, the content of tin is over 95 wt %. One well-known alloy is the SAC305, with 3 wt % Ag, 0.5% Cu and the balance being tin. A disadvantage of SAC solders is however the melting point that is typically in the range of 217-227° C. The higher melting point requires that the reflow process (i.e. the operation wherein solder is melting and a connection is formed to the substrate) has to happen at a relatively high temperature, which increases the risk of failure due to thermal fatigue and the like.

An alternative type of solder is based on tin-bismuth (hereinafter also referred to as SnBi). Commercially available solder alloys based thereon include Sn42Bi58 and Sn42Bi57Ag1, wherein the numbers indicate the weight percentage of the respective element. These solder alloys are low melting, typically around 140° C., but more brittle when compared to SAC solder alloys. Investigations on tin-bismuth alloys were carried out in the early 1990s. Felton et al, ‘The properties of tin-bismuth alloy solders’, Journal of Minerals, Metals & Materials Society (JOM), 45(1993), 28-32, discloses ternary tin-bismuth alloys containing copper (Cu), zinc (Zn) or antimone (Sb) as ternary alloy element in an amount of 1.0 wt %, both for Sn42Bi58 and an Sn60Bi40 alloy. On the basis of wetting areas of a test substrate, the authors observe that the average wetting areas for the Sn—Bi alloys are worse than those for the traditional Sn—Pb alloys. It is concluded that the ternary elements may give rise to coarsening during ageing, and therewith turn out to improve some of the mechanical behaviour of the solders. EP0629467 disclosed Sn—Bi alloys with 42-50 wt % Sn, 46-56 wt % Bi, and at least one of 1-2 wt % Ag, 2-4 wt % Cu and 1-2 wt % In.

However, this development line of the 1990s was given up in favour of the SAC solders. One reason therefore is that bismuth is naturally a brittle element and the Sn—Bi solder alloy is also brittle. Even when the Bi-content of the Bi-alloy is decreased to less than 58%, it becomes brittle because Bi segregates in Sn. A solder joint soldered by using the Sn—Bi solder alloy may generate cracks because of its brittleness when any considerable stress is added thereto so that its mechanical strength may deteriorate. Further, in order to cope with the miniaturisation in electronics, a typical soldering area has decreased over time, and a narrower pitch between the solder pads must be used. As a consequence, less solder is used, which further increases the risk of deterioration of mechanical strength of Sn—Bi alloys.

Only more recently, Sn—Bi has regained attention. Japanese patent document no 2013-00744 discloses a Sn—Bi—Cu—Ni alloy. It is prepared by adding Cu and/or Ni to an eutectic Sn—Bi composition (Sn42Bi58). According to said patent document, this alloy has an improved mechanical strength because any intermetallic compounds having hexagonal closest packing structure are formed in the solder joined portion or on a solder joining interface.

EP2987876A1 relates to an improved Sn—Bi—Cu—Ni alloy with 0.3-1.0 wt % Cu and 0.01-0.06 wt % nickel (Ni) for use in combination with electroless Ni—Au plating on a solder pad. In the examples, solder balls of the said alloy are placed on a PCB containing an electroless Ni—Au plated layer. One of the test parameters is the thickness of a P-rich layer. The phosphorous originates from the the electroless Ni-layer. Upon heating, the Ni diffuses more quickly than the P. This leads, according to said patent document, to formation of a P-rich layer at the interface of the electroless nickel layer and the solder, which reduces mechanical strength. The addition of nickel to the alloy helps to suppress diffusion of Ni therein, and reduces the risk of formation of a separate P-rich layer. The solder alloy may further contain phosphorous (P) and/or germanium (Ge). Testing was done with solder balls containing the solder alloy and an aqueous flux. The 0.3 mm solder balls were placed on a board with copper pads with an electroless Ni—Au finish and were reflowed under a reflow profile with a peak temperature of 210° C. EP3031566A1 discloses an alternative solder for exactly the same problem and using the same test. According to the latter application, the preferred solder alloy consists essentially of 31-59% Bi, 0.15-.0.75% Sb, 0.3-1.0% Cu and 0.002-0.0055% P with the balance being Sn.

However, test with solder balls are not representative for the behaviour of layer-wise applied solder, such as a solder paste or wave-soldered material. First of all, solder balls have a relative high height compared to other solder joints formed in other soldering methods, such as soldering with a solder paste and wave soldering. The resulting lower height of solder joints is more critical for reliability. In fact, field failures have been observed lately with solder chemistries that have passed standardized reliability tests. Additionally, the kinetics and behaviour during reflow soldering of solder balls is different from that of solder paste and wave soldering. A solder ball constitutes a volume of pure solder have a predefined interface with the solder pad. In wave soldering, the solder is applied onto the pad and with solder paste comprising flux and solder powder, the flux should go out of the molten solder.

Moreover, electroless nickel-gold plating is not the only relevant finishing. Recently, alternative finishes are under investigation and in use that reduce costs relative to the electroless nickel-plating. Examples of such finishes are the immersion tin (Sn)-soldering and the Organic Solderability Preservative (OSP). It is desired to obtain a solder alloy that provides with the different finishes an appropriate reliability

### SUMMARY OF THE INVENTION

It is therefore an object of the invention to provide an improved solder alloy with a good reliability for use in a variety of soldering methods, such as wave soldering, reflow soldering, dip soldering, wire soldering, and selective soldering.

It is a further object of the invention to provide a soldering method with high reliability for electronic components with a relatively low stand-off height, i.e a low height of the solder connection, such as less than 200 μm, preferably at most 150 μm, more preferably at most 100 μm, or even at most 50 μm.

It is again a further object of the invention to provide a soldering method for packaged electronic components having both contact pads and an exposed die pad. One example of such an electronic component package is the quad-flat non-leaded (QFN) package.

According to a first aspect, the invention relates to the use of a solder paste comprising a lead free solder alloy and preferably a solder flux for soldering an electronic component package to a substrate. Herein, the lead free solder alloy has an alloy composition containing 38.0 to 42.0 wt % of bismuth (Bi), 0.01-2 wt % of at least one further element chosen from the group of manganese (Mn), copper (Cu) and antimony (Sb), and the balance of Sn, such as 58.0-78.0 wt % tin (Sn). Preferably, the bismuth content is 38.0-41.0 wt %. The preferred tin content is 58.0 to 62.0 wt %, more preferably up to 59.9 wt %. The electronic component package is preferably provided with a plurality of contacts and an exposed die pad, which contacts and which die pads are soldered to associated contacts on the substrate. This use further comprises placement of surface mount devices (SMD) by means of a solder paste, such as passive components, and also soldering by means of pin-in-paste, so as to solder pins of packages into through-holes in the carrier. The latter relates to the soldering of—typically discrete—components having a pin that is to be inserted into a through-hole of a carrier, such as a printed circuit board.

According to a second aspect, the invention relates to a solder paste comprising a lead-free solder alloy and a solder flux, which solder alloy contains 38.0-42.0 wt % bismuth (Bi), 0.01-2 wt % of at least one further element chosen from the group of manganese (Mn), copper (Cu) and antimony (Sb), the balance being tin (Sn). Preferably, the content of tin is 56.0-59.9 wt % and the content of Bi is 38.0 to 41.0 wt %. Zinc and/or phosphorous may be present additionally.

According to a further aspect, the invention relates more specifically to a solder paste comprising lead-free solder alloy having an alloy composition containing 58.0-62.0 wt % tin (Sn), 38.0-41.0 wt % bismuth (Bi), 0.05-0.5 wt % of copper (Cu) and being free of nickel (Ni).

According to another aspect, the invention relates more specifically to a solder paste comprising lead-free solder alloy having an alloy composition comprising 58.0-62.0 wt % tin (Sn), 38.0-41.0 wt % bismuth and 0.01-2.0 wt % antimony (Sb). Optionally manganese may be present.

According to further aspects, the invention relates to the use of a lead-free solder alloy in wave soldering or selective soldering, wherein the lead-free solder alloy has an alloy composition comprising 38.0-42.0 wt % bismuth (Bi), 0.01-2 wt % of at least one further element chosen from the group of manganese (Mn), copper (Cu), and antimony (Sb), the balance being tin (Sn), the alloy composition being free of nickel (Ni). Preferably, the content of tin is 56.0-59.9 wt % and the content of Bi is 38.0 to 42.0 wt %.

The lead-free alloy is thereto provided in a solder bath for wave soldering and for selective soldering. The term ‘selective soldering’ more particularly refers to a process wherein a turbulent wave washes off flux. As a consequence, not the entire area of the substrate that has been sprayed with flux passes through the soldering process.

The invention is based on the insight that the reliability of solder connections, particularly but not exclusively those with a low stand-off height and/or an exposed die pad, is significantly increased by reducing void formation, for instance to less than 10% (average). Void formation is especially a problem in the soldering of so-called QFN packages, but also with other packages, such as QFP and a Land Grid Array (LGA). An LGA package is a flip-chip Ball Grid Array (BGA) shipped without balls, and to be assembled to a substrate with solder paste. Voids may be formed in the soldered connection at various stages of lifetime of a soldered connection. One type of voids is for instance known as the Kirkendall voids, which have a submicron size and are located between the intermetallic compound formed during soldering and a copper land on a carrier. Kirkendall voids are caused by differences in interdiffusion rate of copper and tin, and can grow under influence of thermal aging and thermal cycling during use. Further types of voids are for instance macrovoids, microvoids and shrink hole voids. Macrovoids are formed by outgassing of the paste flux during reflow. The paste flux comprises organic compounds that are volatile at the reflow temperature, to generate organic vapours. If the organic vapours do not vacate the liquid solder prior to its solidification, they are trapped inside the solder connection, creating a void. Microvoids are found at the interface between the intermetallic compound and a copper land on a carrier, due to malperformance of the soldering process, including contaminations, roughness of the lands and a relatively cool reflow profile, for instance of 10-40° C. below a recommended reflow peak temperature. Shrink hole voids are caused by the shrinking of the bulk solder material during solidification.

It was found in investigations leading to the invention, that the use of specific tin-bismuth solder alloys turns out to reduce void formation. In comparative examples, it was observed that outgassing of the solder paste (during reflow) occurs more gradually for tin-bismuth alloys than for SAC-alloys. Further experiments showed that the void formation could be further optimized to levels well below 5% and even below 3%.

Preferably, the alloy was chosen so as to have a liquidus point below 200° C. and a solidus point in between of 130 and 150° C., for instance 135-143° C. This was more particularly achieved if that the alloy was free of silver. For sake of clarity, the solidus and the liquidus point define the lower and the upper limits of a melting range, from entirely solid to entirely liquid. The melting point is therewith reduced in comparison to conventional SAC solders. Such reduction of reflow temperature is clearly advantageous for packages with an exposed die pad so as to prevent failure. The exposed die pad is comparatively big and thermally conductive. Heat is thus quickly transmitted, during reflow, to the encapsulated components, which however have a much lower coefficient of thermal expansion. The specific tin-bismuth solder alloys are not eutectic.

More particularly, the alloy is substantially free of nickel, such that the total amount of nickel is at most 5 ppm, and preferably less.

In a preferred embodiment, the alloy composition was a tin-bismuth solder containing 58.0-62.0 wt % tin (Sn), 38.0-41.0 wt % bismuth (Bi), and at least one further element chosen from the group of manganese (Mn), antimony (Sb), copper (Cu). These class of alloys have a liquidus point of around 175° C., allowing lowering of the reflow temperature to less than 200° C., or even to 180-190° C. The composition may contain some unavoidable impurities. As specified above, the silver content is suitably low, particularly less than 0.3 wt %, preferably less than 0.1 wt %. Most preferably, the composition is substantially free of silver.

Surprisingly good results have further been obtained with solder alloys, wherein the further element is antimony, and optionally manganese is present. Herein, it was observed that the oxidation of metal is significantly reduced compared to SAC solder and to lead-tin solder.

In a further embodiment, the solder alloy is substantially free of copper and phosphorous, and thus is substantially consisting of tin, bismuth and at least one of antimony and manganese. That has been given very good reliability results, and better than when copper and/or phosphorous were included. The inventors believe that—particularly in reflow soldering—a copper or phosphoring doping would diffuse towards the phosphorous and copper in the substrate, and therewith reduce strength of the connection. This demonstrates that the experimental results with solder balls as disclosed in EP2987876A1 and EP3031566A1 are not predictable for the behaviour of a Sn—Bi solder paste.

In accordance with preferred embodiments of the invention, the antimony content is—when present—in the range of 0.01-2.0% by weight. The manganese content is—when present—in the range of 0.01-1.0% by weight. The phosphorous content is—when present—in the range of 0.01-0.5% by weight. The zinc content is—when present—in the range of 0.1-1.0%. Preferably, at most two of the further elements are present, such as a combination of antimony and manganese. More preferably, the total content of any of the specified further elements is at most 2.0% by weight. In most preferred examples, the total content of further elements is at most 1.0% by weight. The solder alloy is suitably present in a solder paste composition that further comprises a flux with a particle size of 10-40 μm, more preferably 15-30 μm, such as 20-25 μm. This particle size is based upon sieving.

The lead-free solder alloy is suitably used in combination with a flux material that is halide-free. The solder flux typically contains an activator, a solvent and an organic foaming agent. Preferably, herein the activator is an organic acid, either a monoacid or a poly acid compound and more suitably an aliphatic acid, such as formic acid, acetic acid, citric acid, lactic acid, oxalic acid. The solvent is suitably a monohydric alcohol or an acetic ester or a mixture thereof. The monohydric alcohol is for instance a C₁-C₄ alkanol. More suitably, the solder flux may contain a rosin, a resin or be free thereof. Suitable resins are for instance polyesters. The solder alloy and the solder flux are suitably present in a volume ratio between 2:1 and 1:2, such as between 1.3:1 and 1:1.3, more preferably between 1.1:1 and 1:1.1.

While the use as a solder paste is particularly preferred, the solder alloy of the invention may alternatively be used in wave soldering, selective soldering, dip soldering, as part of a wire, for placement of SMDs and for pin-in-paste applications. The latter relates to the soldering of—typically discrete—components having a pin that is to be inserted into a through-hole of a carrier, such as a printed circuit board. The term ‘selective soldering’ more particularly refers to a process wherein a turbulent wave washes off flux. As a consequence, not the entire area of the substrate that has been sprayed with flux passes through the soldering process. A highly preferred application is the use of the solder paste for the soldering of packages with an exposed die pad, such as a QFN package.

In again another embodiment, the solder is applied as a solder paste, whereas the electronic component package is provided with solder balls, i.e. as a ball grid array (BGA) package. The solder balls may be of a conventional solder, such as a SAC (tin-silver-copper) solder alloy, such as SAC305, SAC405 and the like. This combination has been experimentally found to give beneficial results in terms of reliability. The reflow temperature may herein be reduced. Furthermore, the size of the solder balls may be decreased, for instance from 300 μm down to at most 200 μm. This size reduction allows cost reduction and miniaturisation. Rather than combining solder balls of a SAC solder with a solder paste of the invention, it is not excluded to apply another type of solder for the balls.

Furthermore, the solder paste of the invention is also suitable for use for assembly of an electronic package that comprises solder bumps within the package. An example hereof is a package wherein an integrated circuit is coupled to a package substrate or to another chip or silicium substrate by means of flip chip. The electronic package could herein be subjected to reflow prior to its shipping to a customer and final assembly, in that the solder paste of the invention can be reflowed at a lower temperature that will not affect the said solder bumps inside the package.

As observed in further tests, the solder paste may be combined with a substrate having any type of finish, including an immersion tin finish, a nickel gold finish and an OSP copper finish. This OSP finish refers to Organic Solderability Preservative. Such an OSP finish turns out less vulnerable for dust and other contaminations that often are present in assembly plants, particularly those located in East Asia.

For sake of clarity, one advantage of the invention is that the lead-free solder alloy of the invention can be used both as a solder paste together with a flux, but also for wave soldering or selective soldering. As a consequence, a substrate such as a PCB can be soldered entirely with a single solder material. The use of selective soldering appears beneficial. It has been found that this type of soldering can be effected with the solder alloy of the invention at an increased speed, for instance of at least 10 mm/s, or also at least 20 mm/s or even at least 30 mm/s. Even with a speed of 50 mm/s good results have been obtained. Use was made herein of soldering temperatures of 200° C. The solder alloy can be applied in a temperature range of 190 to 320° C.

Another advantage of the use of the solder according to the invention, for instance as a solder paste, is that tombstoning is avoided. Tombstoning is the known issue that components and more particularly small SMD components will stand on one end after reflow. The inventors believe that this beneficial result is due in that the solder alloy acts as a glue, in a period before the solder alloy is completely molten.

### EXAMPLES

In order to test reliability, void formation in so-called QFN packages was tested using X-ray analysis. The QFN-package is a package with an exposed die pad surrounded by a plurality of contact pads. The QFN package is a popular choice because of its thin and small profile, low weight and good thermal properties because of the exposed die pad and reduced lead inductance. It is similar to for instance QFP (quad flat package). In 2013, around 32.6 billion QFN packages have been assembled. Further variations on the QFN package are most likely to be developed. QFN packages typically comprise one or more integrated circuits. The plurality of contact pads is present at the four side edges of the package, typically extending both on a side face and the bottom face of the package. The number of contact pads is for instance in the range of 20-100. The pitch (heart-to-heart distance between neighbouring contact pads) is for instance in the range of 0.3-0.7 mm, and the width of the contact pad being about half of the pitch.

When performing X-ray analysis on soldered QFN packages (after reflow), excessive void formation can be observed under the exposed die pad of the QFN package, particularly with the SAC solders as commonly applied. A test carried out by applicant in investigations leading to the invention unexpectedly discovered that the void area can be more than 35% of the total area of the exposed die pad. Furthermore, it was found that the void formation can be different across a single substrate, typically a printed circuit board. This large void formation clearly has a negative impact on thermal conductivity, electric conductivity and mechanical strength of the assembled package.

Several lead-free solder alloys were tested. These are specified in Table 1.

TABLE 1
solder alloys

| | Sn | Bi | Ag | Cu | Sb | Mn |
|---|---|---|---|---|---|---|
| Nr | (wt %) | (wt %) | (wt %) | (wt %) | (wt %) | (wt %) |
| S1* | 96.5 | | 3.0 | 0.5 | | |
| S2* | 99 | | 0.3 | 0.7 | | |
| S3* | 96 | 3 | 0.3 | 0.7 | | |
| S4* | 80 | 20 | | | | |
| S5* | 42 | 57 | 1 | | | |
| S6 | 76.5 | 23 | | | 0.5 | |
| S7 | 70.5 | 28.5 | 0.65 | 0.35 | | |
| S8 | 68.2 | 31.5 | | 0.05 | 0.25 | |
| S9 | 59.9 | 40 | | 0.1 | | |
| S10 | 59.5 | 40 | | | 0.5 | |
| S11 | 59.9 | 40 | | | | 0.1 |
| S12 | 59.8 | 40 | | | 0.1 | 0.1 |

(*= comparative example)

Solder pastes were prepared using Interflux® DP5600 solder flux in a mixture of l0 wt % or 10.5 wt % flux and 89.5 wt % or 90 wt % solder alloy powder. This solder flux is specified for use in combination with low-melting Sn42Bi57Ag1 and Sn42Bi58 solder alloys. The solder paste is screen printed on testboard PCBs, using a MicroDEK 249 stencil printer, and a 120 μm stencil with no reduction. Printing solder paste without any reduction will give the worst voiding results, and was therefore chosen for comparison of different solder alloys. In each experiment, 3 QFN type components are placed on the test PCB. The test PCB has OSP-Cu finish. Use was made of packages supplied by Amkor® as MLF48 packages, with a size of 7×7 mm and an exposed die pad of 5×5 mm and 48 contact pads. After placing the packages on the test PCB, the PCBs are reflowed with an ERSA HotFlow 2/14 reflow oven.

Use was made of a standard linear reflow profile for lead-free soldering, with a peak temperature of 243° C. The standard linear reflow profile was adopted after initial experiments demonstrating that there was no major difference between a standard linear profile (with a peak at 235° C.) and a soak profile (having a soak platform at 200° C. and a peak at 250° C.).

After reflow, the QFN components are inspected using an Y. Cougar FeinFocus X-Ray system for void analysis. Void analysis is performed via contrast detection and describes, when inspecting the soldered component for the topside, the surface area that has voided and the surface area without voiding.

Table 2 shows test results for the voiding

TABLE 2
voiding results for compositions S1-S9

| | Lowest | | | | |
|---|---|---|---|---|---|
| Nr | voiding | Median voiding | Highest voiding | Average | St Dev |
| S1* | 27.18% | 35.37% | 42.11% | 35.68% | 3.74% |
| S2* | 21.03% | 30.75% | 44.54% | 32.91% | 8.79% |
| S3* | 4.10% | 16.00% | 41.01% | 17.12% | 12.51% |
| S4* | 4.92% | 5.90% | 17.96% | 8.83% | 5.45% |
| S5* | 3.96% | 8.56% | 20.21% | 10.51% | 5.78% |
| S6 | 0.82% | 3.73% | 12.12% | 5.05% | 3.77% |
| S7 | 2.27% | 3.36% | 6.37% | 3.46% | 1.73% |
| S8 | 0.5% | 3.20% | 19.55% | 4.99% | 5.35% |
| S9 | 0.0% | 0.55% | 3.88% | 1.18% | 1.23% |

Further experiments were carried out with some further compositions. The test protocol was identical, except that the reflow temperature was chosen to have a peak temperature of 200° C. Table 3 shows the results.

TABLE 3
void test results obtained with solder alloys S10-11-12.

| | Lowest | Median | Highest | | |
|---|---|---|---|---|---|
| Nr | voiding | voiding | voiding | Average | St Dev |
| S10 | 1.0% | 3.27% | 6.47% | 3.79% | 2.10% |
| S11 | 7.02% | 7.81% | 9.18% | 8.05% | 0.89% |
| S12 | 1.83% | 3.57% | 7.75% | 4.13% | 2.13% |

Further tests were carried out with the compositions S9. The compounds were subjected to two different standard reflow profiles, one for lead-free (243° C. peak temperature) and one for leaded components (200° C.). Furthermore the finish of the test board was varied, i.e. as OSP Copper (OSP Cu), Immersion Sn (Imm Sn) and NiAu, as known per se to the skilled person. Voiding results are shown in Table 4

TABLE 4
voiding results for alloy S9 with different finishings
and at different peak temperatures.

| | | Peak | Lowest | | Highest | |
|---|---|---|---|---|---|---|
| Sample | Finish | temperature | value | Median | value | Average |
| S9 | OSP Cu | 243° C. | 1.5% | 1.8% | 3.9% | 2.5% |
| S9 | OSP Cu | 200° C. | 0.3% | 1.1% | 6.5% | 1.4% |
| S9 | NiAu | 243° C. | 0.0% | 0.15% | 1.0% | 0.3% |
| S9 | NiAu | 200° C. | 1.0% | 2.6% | 4.2% | 2.5% |
| S9 | Imm Sn | 200° C. | 0.2% | 1.1% | 5.2% | 1.7% |

1-24. (canceled)

25. A method of soldering an electronic component package and/or a surface mount device (SMD) to a substrate, the method comprising applying by wave-soldering or selective soldering a lead-free solder alloy having an alloy composition consisting substantially of 58.0-62.0 wt % tin (Sn), 38.0-41.0 wt % bismuth (Bi), 0.01-2.0 wt % of antimony (Sb), 0-1.0% of manganese (Mn), wherein the alloy composition is free of nickel (Ni).

26. The method as claimed in claim 25, wherein tin (Sn) is present in the alloy composition in an amount of 58.0-59.9 wt %.

27. The method as claimed in claim 25, wherein the lead-free solder alloy is substantially free of silver (Ag).

28. The method as claimed in claim 25, wherein the solder is applied by selective soldering at a speed of 10 mm/s or greater.

29. The method as claimed in claim 28, wherein the solder is applied by selective soldering at a speed of 20 mm/s or greater.

30. The method as claimed in claim 28, wherein the solder is applied by selective soldering at a speed of 30 mm/s or greater.

31. The method as claimed in claim 25, wherein the solder alloy is applied in a temperature range of 190 to 320° C.

32. The method as claimed in claim 25, wherein the solder alloy is further applied as a solder paste composition comprising a halide-free flux for soldering an electronic component package.

33. the method as claimed in claim 32, wherein the substrate is soldered entirely with a single solder alloy.

34. The method as claimed in claim 32, wherein the solder alloy has a particle size in the range of 10-40 μm as defined by sieve analysis.

35. the method as claimed in claim 34, wherein the solder alloy has a particle size in the range of 20-30 μm as defined by sieve analysis.

36. The method as claimed in claim 32, wherein the electronic component comprises a plurality of contacts and an exposed die pad, which contacts and which die pads are soldered to associated contacts on the substrate.

37. The method as claimed in claim 35, wherein the contacts are contact pads, which are at least partially present on a bottom side of the electric component package.

38. The method as claimed in claim 37, wherein the exposed die pad and the contact pads are arranged in a substantially co-planar way.

39. The method as claimed in claim 32, wherein the electronic component package is a quad-flat no lead (QFN) type package.

40. The method as claimed in claim 32, wherein the electronic component package is provided with solder balls.

41. The method as claimed in claim 40, wherein the solder balls are made of a SAC (tin-silver-copper) solder alloy.

42. The method as claimed in claim 32, wherein the soldering occurs at a reflow temperature of 200° C. or less.

43. The method as claimed in claim 42, wherein the reflow temperature is in the range of 180-190° C.

44. The method as claimed in claim 25, wherein the substrate is provided with a finish of the organic preservative type (OSP).
